(19) United States
(12) Patent Application Publication
(10) Pub. No.: US 2024/0134102 A1
(43) Pub. Date: Apr. 25, 2024

(54) POLARIZING FILM AND DISPLAY DEVICE INCLUDING SAME

(71) Applicant: Samsung Display Co., LTD., Yongin-si (KR)

(72) Inventors: Duk Jin LEE, Yongin-si (KR); Beong-Hun BEON, Yongin-si (KR); Je Seon YEON, Yongin-si (KR); Woo Suk JUNG, Yongin-si (KR)

(73) Assignee: Samsung Display Co., LTD., Yongin-si (KR)

(21) Appl. No.: 18/480,582

(22) Filed: Oct. 4, 2023

(30) Foreign Application Priority Data
Oct. 5, 2022 (KR) 10-2022-0127160

(51) Int. Cl. G02B 5/30; H10K 59/80

(52) U.S. Cl. CPC G02B 5/3016; H10K 59/873; H10K 59/8791

(57) ABSTRACT

A polarization film according to an embodiment includes a first wavelength dispersion layer, and a polarization layer that is disposed on the first wavelength dispersion layer. A wavelength dispersion of the first wavelength dispersion layer satisfies both Relational Expression 1 and Relational Expression 2:
[Relational Expression 1]
0.81<DSP 450 nm=R 450 nm/R 550 nm<0.83
[Relational Expression 2]
1.15<DSP 650 nm=R 650 nm/R 550 nm<1.17.

In Relational Expression 1 and Relational Expression 2, R(γ) denotes a phase difference value in wavelength γ.

### CROSS-REFERENCE TO RELATED APPLICATION(S)

This application claims priority to and benefits of Korean Patent Application No. 10-2022-0127160 under 35 U.S.C. § 119, filed in the Korean Intellectual Property Office on Oct. 5, 2022, the entire contents of which are incorporated herein by reference.

### BACKGROUND

### 1. Technical Field

The disclosure relates to a polarizing film and a display device including the same.

### 2. Description of the Related Art

A display device is a device that implements an image, and may include a liquid crystal display (LCD), an organic light emitting display device (OLED), or an electrophoretic display (EPD).

The display device may be deteriorated by reflected light incident from the outside and reflected from the display device. In order to solve such a problem, research on reducing the reflection of external light by providing an optical film on the display surface of the display device is continuing.

For example, the display device may include a polarization film to prevent light inflow from the outside from being reflected from the front of the display device.

The above information disclosed in this Background section is only for enhancement of understanding of the background of the disclosure, and therefore it may contain information that does not form the prior art that is already known in this country to a person of ordinary skill in the art.

### SUMMARY

Embodiments provide a polarization film with improved color difference generation according to azimuth and a display device including the same.

A polarization film according to an embodiment may include a first wavelength dispersion layer, and a polarization layer that is disposed on the first wavelength dispersion layer. A wavelength dispersion of the first wavelength dispersion layer may satisfy both Relational Expression 1 and Relational Expression 2:

### [Relational Expression 1]

0.81<DSP 450 nm=R 450 nm/R 550 nm<0.83,

### [Relational Expression 2]

1.15<DSP 650 nm=R 650 nm/R 550 nm<1.17.

In Relational Expression 1 and Relational Expression 2, R(γ) may denote a phase difference value in wavelength γ.

The polarization film may further include a second wavelength dispersion layer disposed on the polarization layer, and a wavelength dispersion of the second wavelength dispersion layer may satisfy both Relational Expression 1 and Relational Expression 2.

The first wavelength dispersion layer and the second wavelength dispersion layer may include nematic liquid crystals.

A polarization film according to another embodiment may include a first wavelength dispersion layer, and a polarization layer that is disposed on the first wavelength dispersion layer. A wavelength dispersion of the first wavelength dispersion layer may satisfy one of Relational Expression 1 and Relational Expression 2:

### [Relational Expression 1]

0.81<DSP 450 nm=R 450 nm/R 550 nm<0.83,

### [Relational Expression 2]

1.15<DSP 650 nm=R 650 nm/R 550 nm<1.17.

In Relational Expression 1 and Relational Expression 2, R(γ) may denote a phase difference value in wavelength γ.

The polarization film may further include a second wavelength dispersion layer disposed on the polarization layer, and a wavelength dispersion of the second wavelength dispersion layer may satisfy one of Relational Expression 1 and Relational Expression 2.

Wavelength dispersions of the first wavelength dispersion layer and the second wavelength dispersion layer may satisfy Relational Expression 1.

The first wavelength dispersion layer and the second wavelength dispersion layer may include nematic liquid crystals.

A polarization film according to another embodiment may include a first wavelength dispersion layer, a polarization layer disposed on the first wavelength dispersion layer, and a second wavelength dispersion layer disposed on the polarization layer. A wavelength dispersion of the second wavelength dispersion layer may satisfy both Relational Expression 1 and Relational Expression 2:

### [Relational Expression 1]

0.81<DSP 450 nm=R 450 nm/R 550 nm<0.83,

### [Relational Expression 2]

1.15<DSP 650 nm=R 650 nm/R 550 nm<1.17.

In Relational Expression 1 and Relational Expression 2, R(γ) may denote a phase difference value in wavelength γ.

A wavelength dispersion of the first wavelength dispersion layer may satisfy one of Relational Expression 1 and Relational Expression 2.

The first wavelength dispersion layer and the second wavelength dispersion layer include nematic liquid crystals.

A display device according to an embodiment may include a substrate, a light-emitting element disposed on the substrate, a thin film encapsulation layer disposed on the light-emitting element, and a polarization film disposed on the thin film encapsulation layer. The polarization film may include a first wavelength dispersion layer, and a polarization layer that is disposed on the first wavelength dispersion layer. A wavelength dispersion of the first wavelength dispersion layer may satisfy both Relational Expression 1 and Relational Expression 2:

### [Relational Expression 1]

0.81<DSP 450 nm=R 450 nm/R 550 nm<0.83,

### [Relational Expression 2]

1.15<DSP 650 nm=R 650 nm/R 550 nm<1.17.

In Relational Expression 1 and Relational Expression 2, R(γ) may denote a phase difference value in wavelength γ.

The display device may further include a second wavelength dispersion layer disposed on the polarization layer, wherein a wavelength dispersion of the second wavelength dispersion layer may satisfy both Relational Expression 1 and Relational Expression 2.

The thin film encapsulation layer may have a multi-layered structure of three or more layers.

The first wavelength dispersion layer may be disposed closer to the substrate than the polarization layer.

A display device according to another embodiment may include a substrate, a light- emitting element disposed on the substrate, a thin film encapsulation layer disposed on the light- emitting element, and a polarization film disposed on the thin film encapsulation layer. The polarization film may include a first wavelength dispersion layer, and a polarization layer that is disposed on the first wavelength dispersion layer. A wavelength dispersion of the first wavelength dispersion layer may satisfy one of Relational Expression 1 and Relational Expression 2:

### [Relational Expression 1]

0.81<DSP 450 nm=R 450 nm/R 550 nm<0.83,

### [Relational Expression 2]

1.15<DSP 650 nm=R 650 nm/R 550 nm<1.17.

In Relational Expression 1 and Relational Expression 2, R(γ) may denote a phase difference value in wavelength γ.

The display device may further include a second wavelength dispersion layer disposed on the polarization layer, wherein a wavelength dispersion of the second wavelength dispersion layer may satisfy one of Relational Expression 1 and Relational Expression 2.

Wavelength dispersions of the first wavelength dispersion layer and the second wavelength dispersion layer each may satisfy Relational Expression 1.

A display device according to another embodiment may include a substrate, a light-emitting element disposed on the substrate, a thin film encapsulation layer disposed on the light-emitting element, a polarization film disposed on the thin film encapsulation layer. The polarization film may include a first wavelength dispersion layer, a polarization layer that is disposed on the first wavelength dispersion layer, and a second wavelength dispersion layer that is disposed on the polarization layer. A wavelength dispersion of the second wavelength dispersion layer may satisfy both Relational Expression 1 and Relational Expression 2:

### [Relational Expression 1]

0.81<DSP 450 nm=R 450 nm/R 550 nm<0.83,

### [Relational Expression 2]

1.15<DSP 650 nm=R 650 nm/R 550 nm<1.17.

In Relational Expression 1 and Relational Expression 2, R(γ) may denote a phase difference value in wavelength γ.

A wavelength dispersion of the first wavelength dispersion layer may satisfy one of Relational Expression 1 and Relational Expression 2.

The first wavelength dispersion layer may be disposed closer to the substrate than the second wavelength dispersion layer.

According to embodiments, a polarization film that improves color difference generation according to an azimuth and a display device including the polarization film are provided.

### BRIEF DESCRIPTION OF THE DRAWINGS

FIG. 1 schematically shows a polarizer according to an embodiment.

FIG. 2 schematically illustrates a structure of a display device including the polarization film of FIG. 1.

FIG. 3 and FIG. 4 schematically show a WAD trajectory at the 6 o'clock direction (FIG. 3) and a WAD trajectory at the 4 o'clock direction (FIG. 4) with a viewing angle fixed at 50 degrees for a display device including a wavelength dispersion layer.

FIG. 5 to FIG. 9 schematically represent the principle of color difference according to the azimuth, FIG. 6 and FIG. 7 schematically show a path of light of the absorption axis direction of FIG. 5, and FIG. 8 and FIG. 9 schematically show a path of light of the transmissive axis direction of FIG. 5.

FIG. 10 schematically shows a color difference for each azimuth for a display device with the same structure as in FIG. 11.

FIG. 12 schematically shows a color difference for each azimuth for a display device with the same structure as in FIG. 13.

FIG. 14 schematically shows a polarization film that does not include a second QWP.

FIG. 15 schematically shows a display device that does not include a second QWP.

FIG. 16 schematically shows a color difference measurement for Comparative Example 1 in which QWPs of the above-described Embodiments 1 to 4 do not satisfy Relational Expression 1 and Relational Expression 2.

FIG. 17 schematically shows an area occupied by each of a comparative example and Embodiment 1 to 4 in FIG. 16.

FIG. 18 schematically illustrates a cross-section of a display device according to an embodiment.

### DETAILED DESCRIPTION OF THE EMBODIMENTS

Hereinafter, with reference to accompanying drawings, various embodiments of the disclosure will be described in detail and thus a person of an ordinary skill in the art can practice in the technical field to which the disclosure belongs. The disclosure may be embodied in many different forms and is not limited to the embodiments described herein.

In order to clearly explain the disclosure, parts irrelevant to the description may be omitted, and the same reference numerals refer to the same or similar constituent elements throughout the specification.

In addition, since the size and thickness of each component shown in the drawings may be arbitrarily shown for better understanding and ease of description, the disclosure is not necessarily limited to what is shown in the drawings.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean any combination including “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean any combination including “A, B, or A and B.”

It will be understood that when an element such as a layer, film, region, or substrate is referred to as being “on” another element, it can be directly on the other element or intervening elements may also be present. In contrast, when an element is referred to as being “directly on” another element, there may be no intervening elements present.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

Further, throughout the specification, when a view is referred to as “planar”, it means the case where a target part is viewed from above, and when a view is referred to as “in a cross- section”, it means the case where a cross-section obtained by vertically cutting the target part is viewed from the side.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

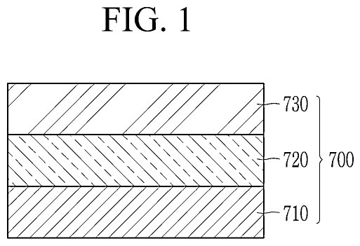

FIG. 1 schematically shows a polarizer according to an embodiment. Referring to FIG. 1, a polarization film 700 according to an embodiment may include a first quarter waveplate (QWP) 710, a polarization layer 720, and a second QWP 730.

The polarization layer 720 may serve to polarize light incident from a light source (not shown) into light in the same direction as a polarization axis. In some embodiments, the polarization layer 720 may include a polarizer or dichroic dye in a polyvinyl alcohol (PVA) film. A dichroic pigment may be an iodine molecule or a dye molecule. In some embodiments, the polarization layer 720 may be formed by stretching a polyvinyl alcohol film in a direction and dipping it in a solution of iodine or dichroic dye. Iodine molecules or dichroic dye molecules may be arranged side by side in the elongation direction. Since iodine molecules and dye molecules show dichroism, they may absorb light vibrating in an elongation direction and transmit light vibrating in a direction perpendicular thereto.

The first QWP 710 and the second QWP 730 may be disposed on both sides of the polarization layer 720, and the polarized light passing through the polarization layer 720 may be phase-delayed by γ/4 to achieve circular polarization. Accordingly, the reflectance of light can be lowered. The first QWP 710 and the second QWP 730 may have wavelength dependence, and a phase retardation value may decrease towards shorter wavelengths.

In an embodiment, wavelength dispersion (DSP) of the first QWP 710 and the second QWP 730 may be expressed as DSP(γ)=R(γ)/R 550 nm. R(γ) may mean a phase difference value at wavelength γ.

An embodiment may be characterized by defining the wavelength dispersion for a specific wavelength of the first QWP 710 or second QWP 730, and, as the wavelength dispersion of each QWP satisfies the corresponding range, a problem of color difference depending on the azimuth in the display device including the QWP can be solved.

Now, the wavelength dispersion of the first QWP 710 and the second QWP 730 of the display device according to an embodiment will be described in detail with reference to the drawings.

In an embodiment, the wavelength dispersion (DSP (450 nm)) for a wavelength of 450 nm of the first QWP 710 may be 0.81 to 0.83. For example, the first QWP 710 may satisfy the following Relational Expression 1.

### [Relational Expression 1]

0.81<DSP (450 nm)=R (450 nm)/R (550 nm)<0.83

The wavelength dispersion (DSP (650 nm)) for a wavelength of 650 nm of the first QWP 710 may be 1.15 to 1.17. For example, the first QWP 710 may satisfy the following Relational Expression 2.

### [Relational Expression 2]

1.15<DSP (650 nm)=R (650 nm)/R (550 nm)<1.17

The first QWP 710 may satisfy both Relational Expression 1 and Relational Expression 2, or only one of Relational Expression 1 or Relational Expression 2. However, the first QWP 710 that satisfies both Relational Expression 1 and Relational Expression 2 may have an improved effect.

The wavelength dispersion (DSP (450 nm)) for a wavelength of 450 nm of the second QWP 730 may be 0.81 to 0.83. For example, the second QWP 730 may satisfy the following Relational Expression 1.

### [Relational Expression 1]

0.81<DSP (450 nm)=R (450 nm)/R (550 nm)<0.83

The wavelength dispersion (DSP (650 nm)) for a wavelength of 650 nm of the second QWP 730 may be 1.15 to 1.17. For example, in the case of the second QWP 730, the following Relational Expression 2 may be satisfied. =[Relational Expression 2]

1.15<DSP (650 nm)=R (650 nm)/R (550 nm)<1.17

The second QWP 730 may satisfy both Relational Expression 1 and Relational Expression 2, or only one of Relational Expression 1 or Relational Expression 2. However, the second QWP 730 that satisfies both Relational Expressions 1 and 2 may have an improved effect.

For example, in the case of an embodiment, the wavelength dispersion of the first QWP 710 and the second QWP 730 may satisfy Relational Expressions 1 and 2. It may be possible to solve the problem of color difference according to the azimuth in the display device including the QWP.

In an embodiment, the first QWP 710 may be disposed closer to the light-emitting element (not shown) than the second QWP 730. For example, the first QWP 710 may polarize the light emitted from the light-emitting element by delaying the phase by γ/4. The second QWP 730 may be disposed closer to the user than the first QWP 710, and visibility can be secured in case that polarization sunglasses are applied. Depending on embodiments, the second QWP 730 may be omitted.

The first QWP 710 and second QWP 730 may include nematic liquid crystals. For example, the nematic liquid crystals may have a structure shown in Structural Formula 1 below.

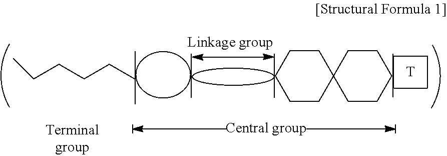

The terminal/linkage group may affect a length and viscosity of liquid crystal molecules. The terminal group may be alkyl, alkoxy, alkenyl, or alkenyloxy having 1 to 20 carbon atoms. The linkage group may be toluene, ester ethylene, C—C bond, OCH₂, or CH₂ₙ. Here, n may be 1 to 20. However, this is only an example and the disclosure is not limited thereto.

In the Structural Formula 1, the central group may affect the refractive index value and the refractive anisotropy characteristic. The central group may include one or more selected from Chemical Formulas 1 to 8, but is not limited thereto.

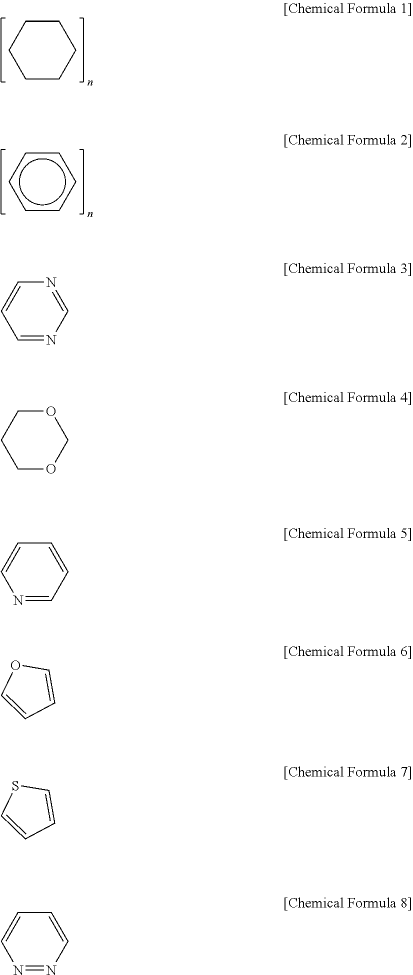

In Chemical Formulas 1 and 2, n may be 1 to 10.

In Structural Formula 1, the T group may affect polarity. T may be selected from among alkyl, alkoxy, CN, and halogen atoms having 1 to 20 carbon atoms.

In Structural Formula 1, a short wavelength refractive index tends to increase depending on an aromatic ring content of the central group. Therefore, the wavelength dispersion may be adjusted by appropriately adjusting a ratio of the aromatic ring of the central group and the terminal group. However, this is just an example, and a QWP satisfying Relational Expression 1 or Relational Expression 2 of the disclosure may be formed by various methods.

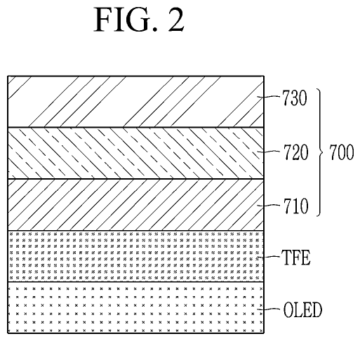

FIG. 2 schematically illustrates a structure of a display device including the polarization film of FIG. 1. Referring to FIG. 2, the display device may include a light-emitting element OLED, a thin film encapsulation layer TFE disposed on the light-emitting element OLED, and a polarization film 700 disposed on the thin film encapsulation layer TFE. Description of the polarization film 700 is omitted as it may be the same or similar as described above. For example, the polarization film 700 may include a first QWP 710, a polarization layer 720, and a second QWP 730, and the wavelength dispersion of the first QWP 710 and the second QWP 730 may satisfy both the following Relational Expressions 1 and 2, respectively.

### [Relational Expression 1]

0.81<DSP 450 nm=R 450 nm/R 550 nm<0.83

### [Relational Expression 2]

1.15<DSP 650 nm=R 650 nm/R 550 nm<1.17

The thin film encapsulation layer TFE may have a multi-layered structure. For example, the thin film encapsulation layer TFE may include two or more layers, and may be formed of three to seven layers depending on embodiments. This may be a structure for improving display quality in a display device, and a white angle difference (WAD) of the display device may be improved by appropriately adjusting a refractive index of a multi-layered thin film encapsulation layer TFE. However, in case that the thin film encapsulation layer TFE has a multi-layered structure, the possibility of color difference according to the azimuth may increase. To solve this problem, the polarization film according to an embodiment may control the wavelength dispersion of the first QWP 710 and the second QWP 730.

Hereinafter, the effect of the polarization film according to an embodiment and the display device including the same will be described in detail with reference to the drawings.

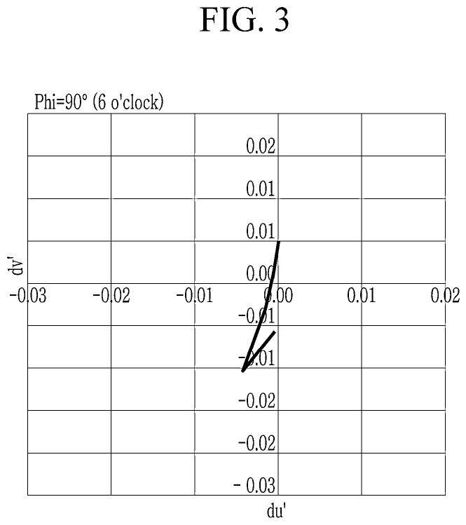

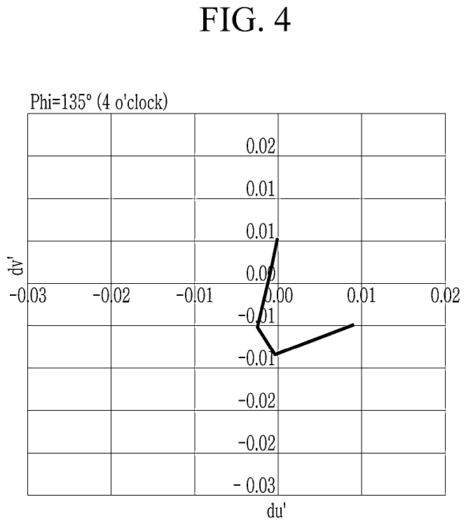

FIG. 3 and FIG. 4 schematically show a WAD trajectory at the 6 o′clock direction (FIG. 3) and a WAD trajectory at the 4 o′clock direction (FIG. 4) with a viewing angle fixed at 50 degrees for a display device including a wavelength dispersion layer. For example, FIG. 3 schematically shows the WAD when viewed from a 90-degree orientation, and FIG. 4 schematically shows the WAD when viewed from a 135-degree orientation. Comparing FIG. 3 and FIG. 4, it may be confirmed that the trajectory of the WAD may be different as the azimuth is changed. This indicates that color difference may occur according to the azimuth of the display device. Particularly, the color difference may occur readily in case that a multilayer (thin film encapsulation layer, etc.) with a large refractive index difference is formed on the emission layer.

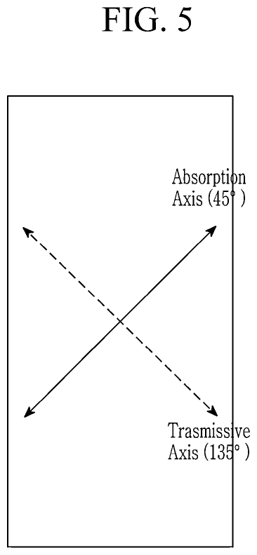

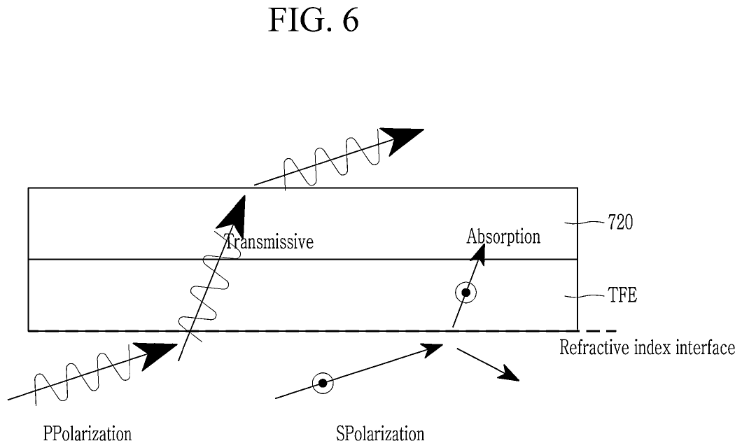

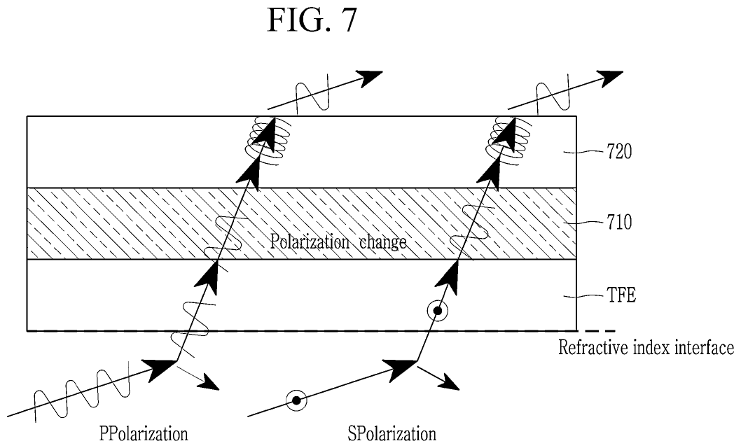

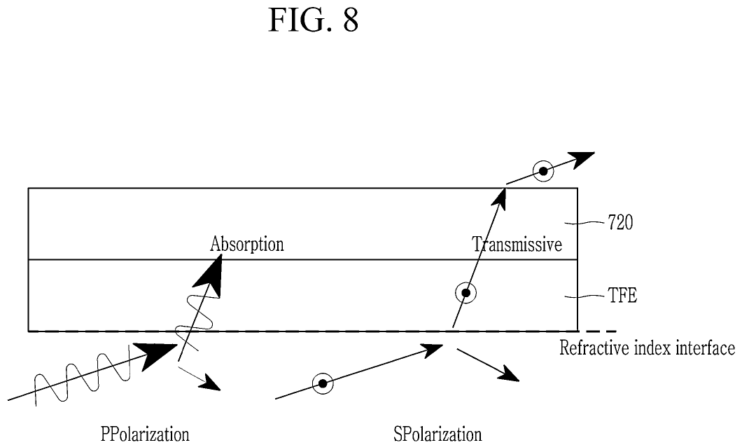

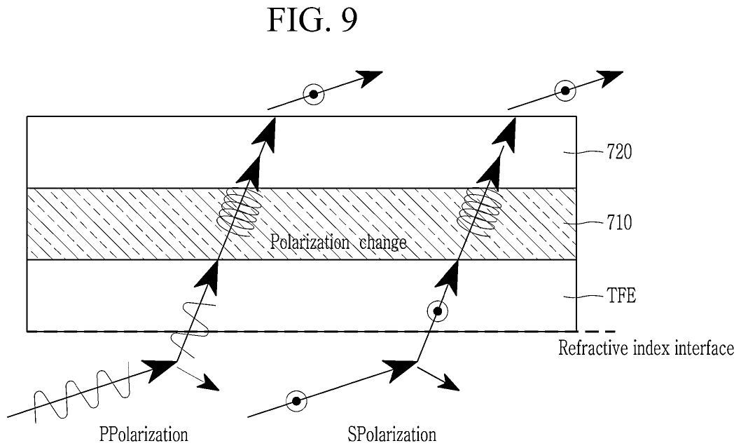

FIG. 5 to FIG. 9 schematically represent the principle of color difference according to the azimuth. FIG. 5 shows an absorption axis direction and a transmissive axis direction. FIG. 6 and FIG. 7 schematically show a path of light of the absorption axis direction of FIG. 5, and FIG. 8 and FIG. 9 schematically show a path of light of the transmissive axis direction of FIG. 5. FIG. 6 and FIG. 8 schematically show a structure that does not include a QWP, and FIG. 7 and FIG. 9 schematically show a structure that includes a QWP.

Comparing FIG. 6 and FIG. 7, the thin film encapsulation layer TFE and the polarization layer 720 may be disposed on an interface (refractive index interface) with the emission layer. In FIG. 7, a QWP 710 disposed between the thin film encapsulation layer TFE and the polarization layer 720 may be further included. In the case of FIG. 6, which is a case of not including a QWP, a difference in the transmittance between the P wave and the S wave may occur in the interface with different refractive indexes on the emission layer. Therefore, P waves may be transmitted, but S waves may not be transmitted. However, in the case of an embodiment of FIG. 7, elliptical polarization may occur in case passing through the QWP 710, and both the P wave and the S wave may pass through the polarization layer 720. After elliptical polarization may be performed in the QWP 710, and a transmittance difference of RGB for each azimuth occurs as it passes through the polarization layer 720, a color difference may be viewed.

Similarly, comparing FIG. 8 and FIG. 9, in FIG. 8, a thin film encapsulation layer TFE and a polarization layer 720 may be disposed on an interface with the emission layer. In FIG. 9, a QWP 710 disposed between the thin film encapsulation layer TFE and the polarization layer 720 may be further included. In the case of FIG. 8, which is a case of not including a QWP, a difference in the transmittance between the P wave and the S wave may occur in the interface with different refractive indexes on the emission layer. Therefore, S waves may be transmitted, but P waves may not be transmitted. However, in the case of an embodiment of FIG. 9, elliptical polarization may occur in case passing through the QWP 710, and both the P wave and the S wave may pass through the polarization layer 720. After elliptical polarization is performed in the QWP 710, a transmittance difference of RGB for each azimuth may occur as it passes through the polarization layer 720, thereby causing a color difference to be viewed.

In case that a multilayered thin film encapsulation layer TFE with many refractive index interfaces is applied, the transmittance difference and color difference may further increase according to the azimuth.

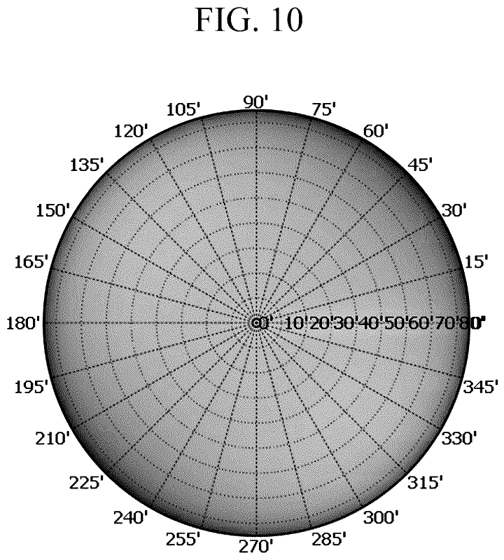

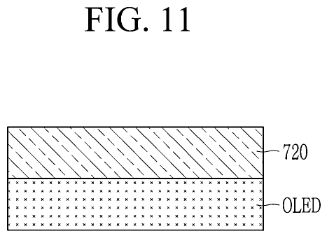

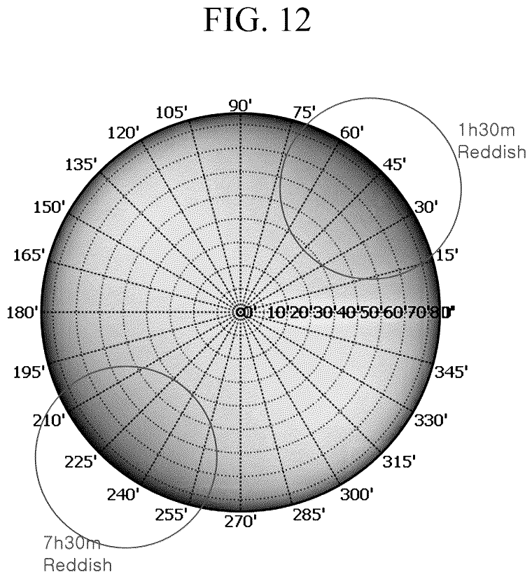

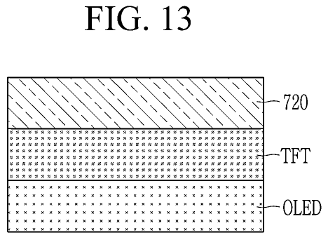

FIG. 10 schematically shows a color difference for each azimuth for a display device with the same structure as in FIG. 11. FIG. 12 schematically shows a color difference for each azimuth for a display device with the same structure as in FIG. 13. In the case of FIG. 10, a polarization layer 720 is disposed on a light-emitting element OLED. In an embodiment of FIG. 12, a multi-layered thin film encapsulation layer TFE is disposed between the light-emitting element OLED and the polarization layer 720.

In the case of FIG. 11, which shows a color difference for each azimuth of the display device of FIG. 10, there may be a slight difference in luminance for each azimuth, but no significant color difference. However, in the case of FIG. 12, a reddish color may be recognized differently from other areas between the azimuth of 15 degrees to 75 degrees and the azimuth of 210 degrees to 255 degrees.

The areas where color difference occurs are circled in FIG. 12.

Accordingly, in the case of a polarization film according to an embodiment and a display device including the same, the first QWP 710, the polarization layer 720, and the second QWP 730 may be included, and the wavelength dispersion of the first QWP 710 and the second QWP 730 may satisfy the following Relational Expression 1 and Relational Expression 2 respectively to solve the color difference occurrence.

### [Relational Expression 1]

0.81<DSP 450 nm=R 450 nm/R 550 nm<0.83

### [Relational Expression 2]

1.15<DSP 650 nm=R 650 nm/R 550 nm<1.17

FIG. 1 and FIG. 2 show a polarization film 700 including both the first QWP 710 and the second QWP 730 and the display device including the polarization film 710 (hereinafter, Embodiment 1), but the second QWP 730 may be omitted depending on embodiments.

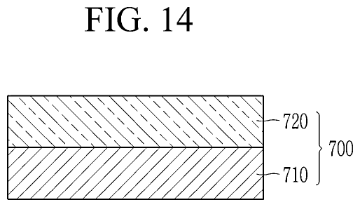

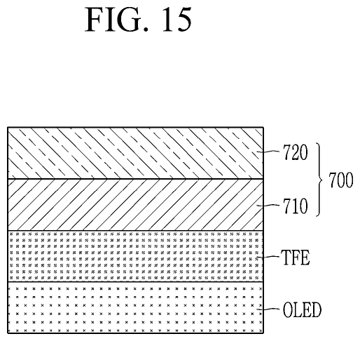

FIG. 14 schematically shows a polarization film that does not include a second QWP. FIG. 15 shows a display device that does not include a second QWP. An embodiment (hereinafter, referred to as Embodiment 2) of FIG. 14 and FIG. 15 may be the same as an embodiment of FIG. 1 and FIG. 2, except that the second QWP 730 may not be included. A detailed description of the same constituent elements is omitted. In FIG. 14 and FIG. 15, the wavelength dispersion DSP of the first QWP 710 may satisfy both Relational Expressions 1 and 2 below.

### [Relational Expression 1]

0.81<DSP 450 nm=R 450 nm/R 550 nm<0.83

### [Relational Expression 2]

1.15<DSP 650 nm=R 650 nm/R 550 nm<1.17

In FIG. 1 and FIG. 2, the first QWP 710 and the second QWP 730 both may satisfy Relational Expressions 1 and 2, but only one of the first QWP 710 and the second QWP 730 may satisfy Relational Expressions 1 and 2 depending on embodiments. For example, the second QWP 730 may satisfy both of the following Relational Expressions 1 and 2, and the first QWP 710 may not satisfy Relational Expressions 1 and 2 (hereinafter, Embodiment 3).

### [Relational Expression 1]

0.81<DSP 450 nm=R 450 nm/R 550 nm<0.83

### [Relational Expression 2]

1.15<DSP 650 nm=R 650 nm/R 550 nm<1.17

Similarly, in the opposite case, the first QWP 710 may satisfy both Relational Expressions 1 and 2, and the second QWP 730 may not satisfy Relational Expressions 1 and 2.

In FIG. 1 and FIG. 2, the first QWP 710 and the second QWP 730 may satisfy both of Relational Expressions 1 and 2, but depending on embodiments, the first QWP 710 and the second QWP 730 may satisfy only one of Relational Expression 1 and Relational Expression 2. For example, the first QWP 710 and the second QWP 730 may satisfy Relational Expression 1, and may not satisfy Relational Expression 2 (hereinafter, Embodiment 4).

Similarly, in the opposite case, the first QWP 710 and the second QWP 730 may satisfy Relational Expression 1 and may not satisfy Relational Expression 1.

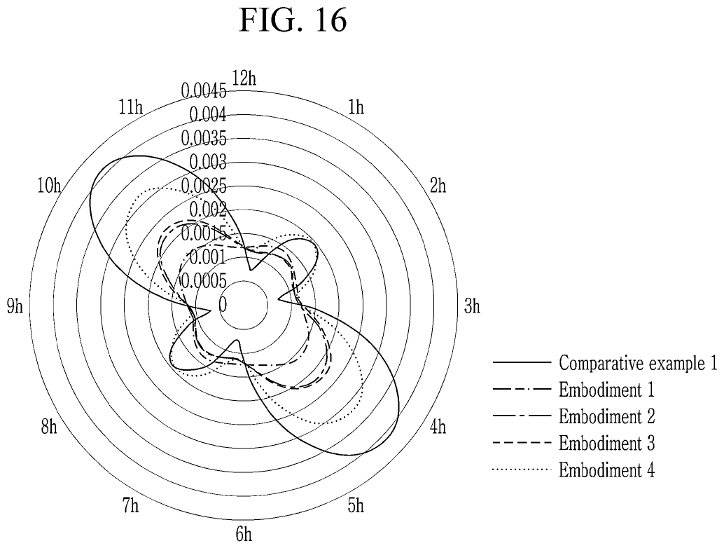

FIG. 16 schematically shows a color difference measurement for Comparative Example 1 in which QWPs of the above-described Embodiments 1 to 4 do not satisfy Relational Expression 1 and Relational Expression 2. FIG. 16 illustrates that in case measuring the color difference, the viewing angle is 60 degrees, and the color difference is measured while changing the azimuth from 0 degrees to 360 degrees.

The wavelength dispersion of Comparative Example 1 and Embodiments 1 to 4 is summarized in Table 1 below.

TABLE 1

| | First QWP | Second QWP |
|---|---|---|
| Comparative | Both Relational | Both Relational |
| Example 1 | Expressions 1 and 2 | Expressions 1 and 2 |
| | are not satisfied (X) | are not satisfied (X) |
| Embodiment 1 | Both Relational | Both Relational |
| | Expressions 1 and 2 | Expressions 1 and 2 |
| | are satisfied (◯) | are satisfied (◯) |
| Embodiment 2 | Both Relational | Not included |
| | Expressions 1 and 2 | |
| | are satisfied (◯) | |
| Embodiment 3 | Both Relational | Both Relational |
| | Expressions 1 and 2 | Expressions 1 and 2 |
| | are not satisfied (X) | are satisfied (◯) |
| Embodiment 4 | Relational Expression | Relational Expression |
| | 1 is satisfied (◯) | 1 is satisfied (◯) |

Referring to FIG. 16, in the case of Comparative Example 1, it may be confirmed that a large difference in color difference appeared for each azimuth. In contrast, in the case of Embodiment 1, in which both the first wavelength dispersion layer and the second wavelength dispersion layer satisfy both Relational Expression 1 and Relational Expression 2, the graph shape appears close to a circle, and it can be confirmed that the difference in color difference by azimuth is not large. Although there may be a difference depending on embodiments, in the case of Embodiments 2, 3, and 4, it may be confirmed that the color difference for each azimuth may be improved compared to Comparative Example 1.

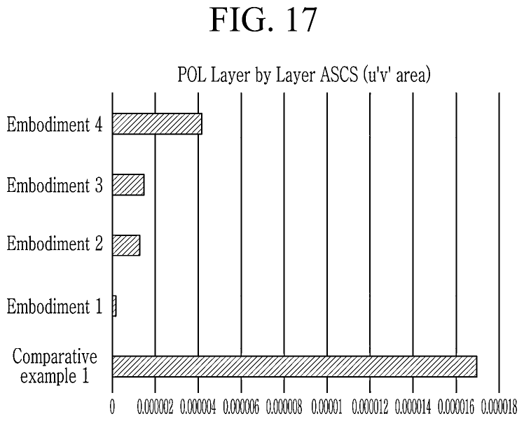

FIG. 17 schematically shows an area occupied by each of a comparative example and Embodiment 1 to 4 in FIG. 16. Referring to FIG. 17, although a distribution area where a color difference occurs may be compared, it can be confirmed that the color difference occurrence is significantly improved in Embodiments 1 to 4 compared to the comparative example. As shown in FIG. 16, Embodiment 1 showed the highest effect, and although there may be a difference in degree, it may be confirmed that Embodiments 2 to 4 also had an improved effect compared to the comparative example.

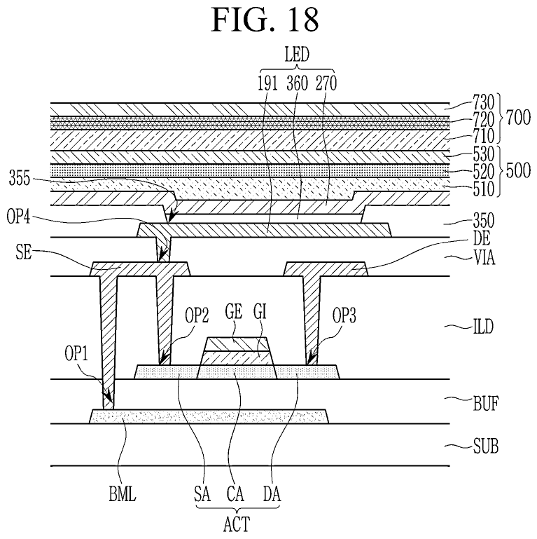

Now, a display device according to an embodiment will be briefly described below with reference to drawings. FIG. 18 schematically illustrates a cross-section of a display device according to an embodiment. FIG. 18 schematically illustrates a part of a cross-section for better comprehension and ease of description, and the disclosure is not limited thereto.

Referring to FIG. 18, a substrate SUB may be disposed. The substrate SUB may include at least one of polystyrene, polyvinyl alcohol, poly(methyl methacrylate), polyethersulfone, polyacrylate, polyetherimide, polyethylene naphthalate, polyethylene terephthalate, polyphenylene sulfide, polyarylate, polyimide, polycarbonate, cellulose triacetate, and cellulose acetate propionate. The substrate SUB may be a rigid substrate or a flexible substrate that can be bent, folded, rolled, and the like. The substrate SUB s may be single-layered or multi-layered. The substrate SUB may be alternately laminated with at least one base layer and at least one inorganic layer including a sequentially laminated polymer resin.

A light blocking layer BML may be disposed on the substrate SUB. The light blocking layer BML may include aluminum (Al), silver (Ag), magnesium (Mg), gold (Au), nickel (Ni), chromium (Cr), calcium (Ca), molybdenum (Mo), titanium (Ti), tungsten (W), and/or copper (Cu), and a metal oxide, and may have a single-layer or multi-layered structure including the same.

A buffer layer BUF may be disposed on the light blocking layer BML. The buffer layer BUF may include a silicon oxide (SiOₓ), a silicon nitride (SiNₓ), a silicon oxynitride (SiOₓN_{y}), and/or amorphous silicon (Si).

The buffer layer BUF may include a first opening OP1 overlapping the light blocking layer BML. In the first opening OP1, the source electrode SE may be connected to the light blocking layer BML.

A semiconductor layer ACT may be disposed on the buffer layer BUF. The semiconductor layer ACT may include polycrystalline silicon. The semiconductor layer ACT may include a channel area CA overlapping the gate electrode GE and a source area SA and a drain area DA disposed on both sides of the channel area.

A gate insulating layer GI may be disposed on the semiconductor layer ACT. The gate insulating layer GI may include a silicon oxide (SiOₓ), a silicon nitride (SiNₓ), and a silicon oxynitride (SiOₓN_{y}), and may have a single-layer or multi-layered structure including the same.

The gate insulating layer GI may overlap and be disposed with the channel area CA of the semiconductor layer ACT. A gate conductive layer including a gate electrode GE may be disposed on the gate insulating layer GI. The gate conductive layer may include molybdenum (Mo), aluminum (Al), copper (Cu), titanium (Ti), and a metal oxide, and may have a single-layered or multi-layered structure including the same.

The gate electrode GE may be formed in the same process as the gate insulating layer GI and have the same planar shape. The gate electrode GE may be disposed overlapping in the vertical direction on the semiconductor layer ACT and the plane of the substrate SUB.

An interlayer insulating layer ILD may be disposed on the semiconductor layer ACT and the gate electrode GE. The interlayer insulating layer ILD may include a silicon oxide (SiOₓ), a silicon nitride (SiNₓ), and a silicon oxynitride (SiOₓN_{y}), and may have a single-layered or multi-layered structure including the same. In case that the interlayer insulating layer ILD has a multi-layered structure including a silicon nitride and a silicon oxide, the layer including a silicon nitride may be disposed closer to the substrate SUB than the layer including a silicon oxide.

The interlayer insulating layer ILD may include a first opening OP1 overlapping the light blocking layer BML, a second opening OP2 overlapping the source area SA of the semiconductor layer ACT, and a third opening OP3 overlapping the drain area DA.

A data conductive layer including the source electrode SE and the drain electrode DE may be disposed on the interlayer insulating layer ILD. The data conductive layer may include aluminum (Al), silver (Ag), magnesium (Mg), gold (Au), nickel (Ni), chromium (Cr), calcium (Ca), molybdenum (Mo), titanium (Ti), tungsten (W), and/or copper (Cu), and a metal oxide, and may have a single-layer or multi-layered structure including the same.

The source electrode SE may contact the light blocking layer BML at the first opening OP1 and may contact the source area SA of the semiconductor layer ACT at the second opening OP2.

The drain electrode DE may contact the drain area DA of the semiconductor layer ACT at the third opening OP3.

The insulating layer VIA may be disposed on the data conductive layer. The insulating layer VIA may include an organic insulating material such as general-purpose polymers such as Poly(methyl methacrylate) (PMMA) or Polystyrene (PS), polymer derivatives with phenolic groups, acryl-based polymers, imide-based polymers, polyimide, and/or siloxane-based polymers.

The insulating layer VIA may include a fourth opening OP4 overlapping the source electrode SE. The first electrode 191 may be disposed on the insulating layer VIA. A partition wall or bank 350 may be disposed on the insulating layer VIA and the first electrode 191. The bank 350 may include an opening 355 overlapping the first electrode 191. An emission layer 360 may be disposed within the opening 355. A second electrode 270 may be disposed on the bank 350 and the emission layer 360. The first electrode 191, the emission layer 360, and the second electrode 270 may form a light-emitting element LED.

A thin film encapsulation layer 500 including a first layer 510, a second layer 520, and a third layer 530 may be disposed on the second electrode 270. Each of the first layer 510, the second layer 520, and the third layer 530 of the thin film encapsulation layer TFE may include an organic material or an inorganic material. The thin film encapsulation layer TFE is shown as three layers in FIG. 18, but the thin film encapsulation layer TFE may have a multi-layered structure. For example, the thin film encapsulation layer TFE may have 5 or more layers.

A polarization film 700 may be disposed on the thin film encapsulation layer TFE. The polarization film 700 may include a first QWP 710, a polarization layer 720, and a second QWP 730. The description of the polarization film 700 is omitted as it may be the same as described above. The wavelength dispersion of the first QWP 710 and the second QWP 730 may satisfy the following Relational Expressions 1 and 2.

### [Relational Expression 1]

0.81<DSP 450 nm=R 450 nm/R 550 nm<0.83

### [Relational Expression 2]

1.15<DSP 650 nm=R 650 nm/R 550 nm<1.17

Depending on embodiments, each of the QWPs 710 and 730 may satisfy both Relational Expressions 1 and 2, or only some of them.

In the case of a polarization film including QWP 710 and 730 that satisfies this relational expression and a display device including the polarization film, color difference for each azimuth of the display device can be improved.

While this disclosure has been described in connection with what is considered to be practical embodiments, it is to be understood that the disclosure is not limited to the disclosed embodiments. On the contrary, it is intended that this disclosure is interpreted to cover various modifications and equivalent arrangements included within the spirit and scope thereof.

What is claimed is:

1. A polarization film, comprising:
a first wavelength dispersion layer; and
a polarization layer that is disposed on the first wavelength dispersion layer, wherein a wavelength dispersion of the first wavelength dispersion layer satisfies both Relational Expression 1 and Relational Expression 2:
[Relational Expression 1]
0.81<DSP 450 nm=R 450 nm/R 550 nm<0.83,
[Relational Expression 2]
1.15<DSP 650 nm=R 650 nm/R 550 nm<1.17, and
in Relational Expression 1 and Relational Expression 2, R(γ) denotes a phase difference value in wavelength γ.

2. The polarization film of claim 1, further comprising:
a second wavelength dispersion layer disposed on the polarization layer, wherein
a wavelength dispersion of the second wavelength dispersion layer satisfies both Relational Expression 1 and Relational Expression 2.

3. The polarization film of claim 2, wherein
the first wavelength dispersion layer and the second wavelength dispersion layer include nematic liquid crystals.

4. A polarization film, comprising:
a first wavelength dispersion layer; and
a polarization layer that is disposed on the first wavelength dispersion layer, wherein
a wavelength dispersion of the first wavelength dispersion layer satisfies one of Relational Expression 1 and Relational Expression 2:
[Relational Expression 1]
0.81<DSP 450 nm=R 450 nm/R 550 nm<0.83,
[Relational Expression 2]
1.15<DSP 650 nm=R 650 nm/R 550 nm<1.17, and
in Relational Expression 1 and Relational Expression 2, R(γ) denotes a phase difference value in wavelength γ.

5. The polarization film of claim 4, further comprising a second wavelength dispersion layer disposed on the polarization layer, wherein a wavelength dispersion of the second wavelength dispersion layer satisfies one of Relational Expression 1 and Relational Expression 2.

6. The polarization film of claim 5, wherein
wavelength dispersions of the first wavelength dispersion layer and the second wavelength dispersion layer satisfy Relational Expression 1.

7. The polarization film of claim 5, wherein
the first wavelength dispersion layer and the second wavelength dispersion layer include nematic liquid crystals.

8. A polarization film, comprising:
a first wavelength dispersion layer;
a polarization layer disposed on the first wavelength dispersion layer; and
a second wavelength dispersion layer disposed on the polarization layer, wherein
a wavelength dispersion of the second wavelength dispersion layer satisfies both Relational Expression 1 and Relational Expression 2:
[Relational Expression 1]
0.81<DSP 450 nm=R 450 nm/R 550 nm<0.83,
[Relational Expression 2]
1.15<DSP 650 nm=R 650 nm/R 550 nm<1.17, and
in Relational Expression 1 and Relational Expression 2, R(γ) denotes a phase difference value in wavelength γ.

9. The polarization film of claim 8, wherein
a wavelength dispersion of the first wavelength dispersion layer satisfies one of Relational Expression 1 and Relational Expression 2.

10. The polarization film of claim 9, wherein
the first wavelength dispersion layer and the second wavelength dispersion layer include nematic liquid crystals.

11. A display device, comprising:
a substrate;
a light-emitting element disposed on the substrate;
a thin film encapsulation layer disposed on the light-emitting element; and
a polarization film disposed on the thin film encapsulation layer, the polarization film comprising:
a first wavelength dispersion layer; and
a polarization layer that is disposed on the first wavelength dispersion layer, wherein
a wavelength dispersion of the first wavelength dispersion layer satisfies both Relational Expression 1 and Relational Expression 2:
[Relational Expression 1]
0.81<DSP 450 nm=R 450 nm/R 550 nm<0.83,
[Relational Expression 2]
1.15<DSP 650 nm=R 650 nm/R 550 nm<1.17, and
in Relational Expression 1 and Relational Expression 2, R(γ) denotes a phase difference value in wavelength γ.

12. The display device of claim 11, further comprising a second wavelength dispersion layer disposed on the polarization layer,
wherein a wavelength dispersion of the second wavelength dispersion layer satisfies both Relational Expression 1 and Relational Expression 2.

13. The display device of claim 11, wherein
the thin film encapsulation layer has a multi-layered structure of three or more layers.

14. The display device of claim 11, wherein
the first wavelength dispersion layer is disposed closer to the substrate than the polarization layer.

15. A display device, comprising:
a substrate;
a light-emitting element disposed on the substrate;
a thin film encapsulation layer disposed on the light-emitting element; and
a polarization film disposed on the thin film encapsulation layer, the polarization film comprising:
a first wavelength dispersion layer; and
a polarization layer that is disposed on the first wavelength dispersion layer, wherein
a wavelength dispersion of the first wavelength dispersion layer satisfies one of Relational Expression 1 and Relational Expression 2:
[Relational Expression 1]
0.81<DSP 450 nm=R 450 nm/R 550 nm<0.83,
[Relational Expression 2]
1.15<DSP 650 nm=R 650 nm/R 550 nm<1.17, and
in Relational Expression 1 and Relational Expression 2, R(X) denotes a phase difference value in wavelength γ.

16. The display device of claim 15, further comprising a second wavelength dispersion layer disposed on the polarization layer,
wherein a wavelength dispersion of the second wavelength dispersion layer satisfies one of Relational Expression 1 and Relational Expression 2.

17. The display device of claim 16, wherein
wavelength dispersions of the first wavelength dispersion layer and the second wavelength dispersion layer each satisfy Relational Expression 1.

18. A display device, comprising:
a substrate;
a light-emitting element disposed on the substrate;
a thin film encapsulation layer disposed on the light-emitting element; and
a polarization film disposed on the thin film encapsulation layer, the polarization film comprising:
a first wavelength dispersion layer;
a polarization layer that is disposed on the first wavelength dispersion layer; and
a second wavelength dispersion layer that is disposed on the polarization layer, wherein
a wavelength dispersion of the second wavelength dispersion layer satisfies both Relational Expression 1 and Relational Expression 2:
[Relational Expression 1]
0.81<DSP 450 nm=R 450 nm/R 550 nm<0.83,
[Relational Expression 2]
1.15<DSP 650 nm=R 650 nm/R 550 nm<1.17, and
in Relational Expression 1 and Relational Expression 2, R(γ) denotes a phase difference value in wavelength γ.

19. The display device of claim 18, wherein a wavelength dispersion of the first wavelength dispersion layer satisfies one of Relational Expression 1 and Relational Expression 2.

20. The display device of claim 18, wherein the first wavelength dispersion layer is disposed closer to the substrate than the second wavelength dispersion layer.
